(19) United States
(12) Patent Application Publication
(10) Pub. No.: US 2025/0189894 A1
(43) Pub. Date: Jun. 12, 2025

(54) PHOTOSENSITIVE SURFACE TREATING AGENT, PATTERN FORMATION SUBSTRATE, LAMINATE, TRANSISTOR, PATTERN FORMING METHOD AND METHOD OF PRODUCING TRANSISTOR

(71) Applicant: NIKON CORPORATION, Tokyo (JP)

(72) Inventors: Yusuke KAWAKAMI, Yokohama-shi (JP); Kazuo YAMAGUCHI, Mitaka-shi (JP); Michiko ITOU, Yokohama-shi (JP)

(73) Assignee: NIKON CORPORATION, Tokyo (JP)

(21) Appl. No.: 19/057,306

(22) Filed: Feb. 19, 2025

Related U.S. Application Data
(63) Continuation of application No. PCT/JP2023/030083, filed on Aug. 22, 2023.

(30) Foreign Application Priority Data
Aug. 22, 2022 (JP) 2022-131902

(51) Int. Cl. G03F 7/075; C23C 18/16; G03F 7/32; H01L 21/027; H01L 21/288; H10D 64/01

(52) U.S. Cl. CPC G03F 7/0754; C23C 18/1608; G03F 7/322; H01L 21/0274; H01L 21/288; H10D 64/01

(57) ABSTRACT

A photosensitive surface treating agent containing a compound represented by the following Formula (M1). (In Formula (M1), R¹ is a hydrogen atom, a tert-butoxycarbonyl group or an ester-based protecting group, R² is a hydrogen atom or an alkyl group having 1 to 6 carbon atoms, m is an integer of 1 or more, and X is a halogen atom or an alkoxy group.

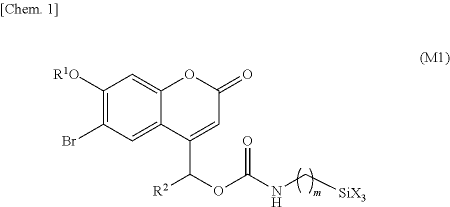

### CROSS-REFERENCE TO RELATED APPLICATIONS

The present application is a continuation application of International Application No. PCT/JP2023/030083, filed on Aug. 22, 2023, which claims priority to Japanese Patent Application No. 2022-131902, filed on Aug. 22, 2022, the contents of each of which are incorporated herein by reference.

### TECHNICAL FIELD

The present invention relates to a photosensitive surface treating agent, a pattern formation substrate, a laminate, a transistor, a pattern forming method and a method of producing a transistor.

### BACKGROUND ART

In recent years, in the production of microdevices such as semiconductor elements, integrated circuits, and organic EL display devices, a method of forming patterns with different surface properties on a substrate, and preparing a microdevice using differences in the surface properties has been proposed.

As a pattern forming method using the difference in the surface properties on a substrate, for example, there is a method of forming a region in which chemically active substituents are generated on a part of the substrate. By this method, a metal material, an organic material or an inorganic material can be adhered to a part of the substrate.

An electroless plating treatment is a technique for adhering a metal material onto a substrate to form a metal film. For example, Patent Document 1 discloses a technique for forming a fine wiring by an electroless plating treatment. Specifically, Patent Document 1 discloses that a catalyst activation layer and a photoresist are used to perform photo-patterning by etching or lift-off after one surface is plated.

### CITATION LIST

### Patent Document

Patent Document 1: Japanese Unexamined Patent Application, First Publication No. 2006-2201

### SUMMARY OF INVENTION

A first aspect of the present invention is a photosensitive surface treating agent containing a compound represented by the following Formula (M1).

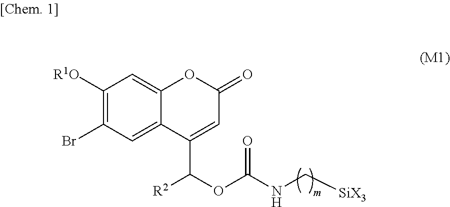

(in Formula (M1), R¹ is a hydrogen atom, a tert-butoxycarbonyl group or an ester-based protecting group, R² is a hydrogen atom or an alkyl group having 1 to 6 carbon atoms, m is an integer of 1 or more, and X is a halogen atom or an alkoxy group).

### BRIEF DESCRIPTION OF DRAWINGS

FIG. 1 Schematic views illustrating a pattern forming method of the present embodiment.

FIG. 2 Schematic views illustrating a method of producing a transistor according to the present embodiment.

FIG. 3A Optical microscope images of L/S=100/100, 5/5 processed in the plated wiring productions 1 to 4 on a PET substrate.

FIG. 3B An optical microscope image of L/S=1/1 to 9/9 um processed in the plated wiring production 3 on a PET substrate.

FIG. 4A A molecular structure of a resin film on a PET substrate.

FIG. 4B An overall image of a PET substrate processed in the plated wiring production 5.

### DESCRIPTION OF EMBODIMENTS

### Photosensitive Surface Treating Agent

A photosensitive surface treating agent of the present invention contains a compound represented by the following Formula (M1).

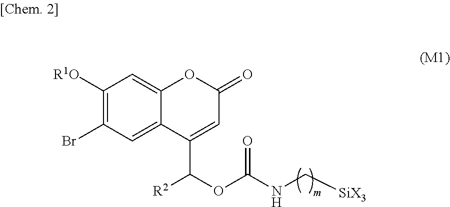

(in Formula (M1), R¹ is a hydrogen atom, a tert-butoxycarbonyl group or an ester-based protecting group, R² is a hydrogen atom or an alkyl group having 1 to 6 carbon atoms, m is an integer of 1 or more, and X is a halogen atom or an alkoxy group).

In Formula (M1), R¹ is a hydrogen atom, a tert-butoxycarbonyl group or an ester-based protecting group.

Examples of ester-based protecting groups include an acetyl (Ac) group, a pivaloyl (Pv) group, a propoxycarbonyl group, a tert-butoxycarbonyl group, and a benzoyl group.

As long as the structure is for protecting a hydroxyl group, it is not particularly limited thereto, and for example, acetal-based protecting groups such as methoxymethyl (MOM), methoxyethoxymethyl (MEM), and 2-tetrahydropyranyl (THP), ether-based protecting groups such as methyl, tert-butyl (tBu) trytyl (Tr), benzyl (Bn), p-methoxybenzyl, trimethylsilyl (TMS), triethylsilyl (TES), and t-butyldimethylsilyl (TBDMS), as well as any protecting group and any deprotection conditions described in Greene's Protective Groups in Organic Synthesis 5th Edition (2014, published by John Wiley & Sons, Inc.) can be applied.

Among these, in consideration of stability, high protection and deprotection reactivity, ease of synthesis and the like, R¹ is preferably a tert-butoxycarbonyl group.

In Formula (M1), R² is a hydrogen atom or an alkyl group having 1 to 6 carbon atoms. Examples of alkyl groups having 1 to 6 carbon atoms include a methyl group, ethyl group, propyl group, isopropyl group, n-butyl group, tert-butyl group, hexyl group, and cyclohexyl group.

In Formula (M1), m is an integer of 1 or more, and X is a halogen atom or an alkoxy group. Examples of halogen atoms represented by X include a fluorine atom, a chlorine atom, a bromine atom and an iodine atom.

X is preferably an alkoxy group. Examples of alkoxy groups for X include —O—(CH₃), and —O—(CH₂)n(CH₃). n is a natural number of 1 to 3.

In Formula (M1), when a photosensitive surface treating agent containing a compound in which R¹ is a tert-butoxycarbonyl group is applied to a substrate, as shown below, SiX₃ adheres to the substrate, and a resin film is formed. This resin film has reduced photosensitivity because a hydroxy group is protected by a tert-butoxycarbonyl group (hereinafter sometimes referred to as “Boc” in the formula).

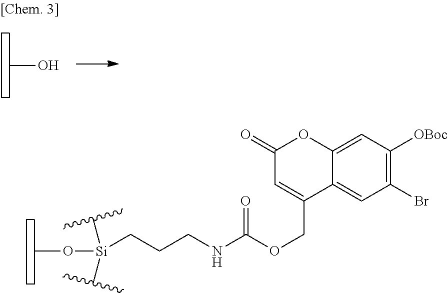

When the resin film is subjected to a deprotection treatment, as shown below, the tert-butoxycarbonyl group is eliminated, a hydroxy group is generated, and a photosensitive resin film is formed.

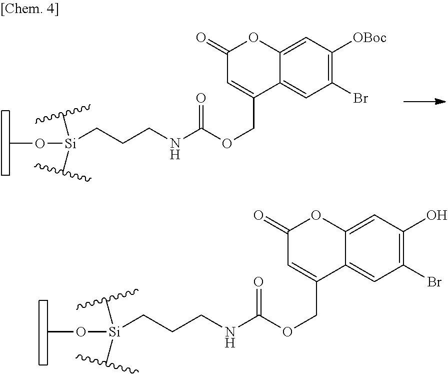

When light is emitted to the obtained photosensitive resin film, nitrobenzyl groups are eliminated and amines are generated on the surface of the substrate. A metal material, an organic material or an inorganic material can be adhered to a portion in which amines are generated.

According to the photosensitive surface treating agent of the present embodiment, when a metal material is disposed in the amine-generated portion formed on the surface of the substrate, a metal pattern with a line width of 5 μm or less can be formed on the surface of the substrate without using a photoresist step, a developing step, or an etching step.

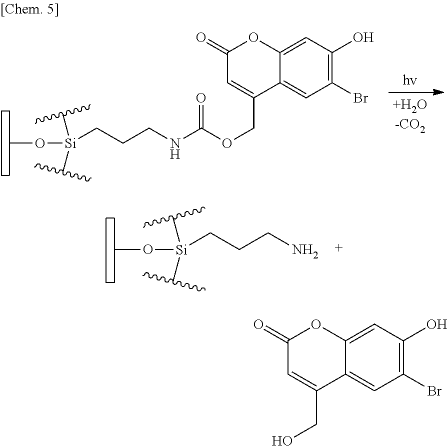

Since the photosensitivity is reduced in the resin film state, the photosensitive surface treating agent can be applied to a substrate and then stably stored without undergoing photolysis. According to the present invention, the photosensitive surface treating agent can be applied to a substrate and stored, and can be used after deprotection immediately before pattern formation.

When a photosensitive surface treating agent containing a compound in which R¹ is a tert-butoxycarbonyl group in Formula (M1) is used, the deprotection method is specifically deprotection using hydrolysis under acidic conditions using hydrochloric acid or trifluoroacetic acid.

When a photosensitive surface treating agent containing a compound in which R¹ is an ester-based protecting group in Formula (M1) is used, the deprotection method is specifically deprotection using hydrolysis or hydride reduction under acidic conditions or basic conditions.

Specific examples of compounds represented by Formula (M1) are shown below.

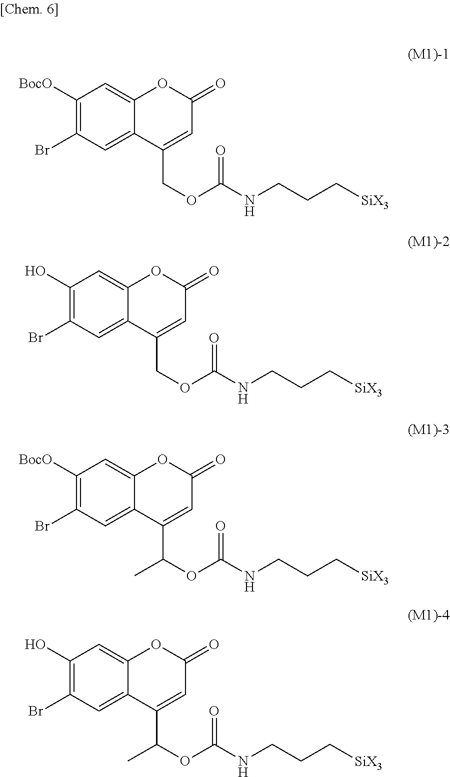

### Method of Producing Compound

A compound represented by Formula (M1) can be produced by the following method.

First, 6-bromo-4-hydroxymethyl-7-hydroxycoumarin is synthesized by the method described in examples.

When the compound represented by Formula (M1) is a compound in which R¹ is a hydrogen atom, the compound represented by Formula (M1) in which R¹ is a hydrogen atom can be synthesized by reacting 6-bromo-4-hydroxymethyl-7-hydroxycoumarin with an aminosilane compound.

When the compound represented by Formula (M1) is a compound in which R¹ is a tert-butoxycarbonyl group, first, 6-bromo-4-hydroxymethyl-7-hydroxycoumarin is reacted with a compound containing a tert-butoxycarbonyl group to synthesize 6-bromo-7-tert-butoxycarbonyloxy-4-hydroxymethylcoumarin.

Examples of compounds containing a tert-butoxycarbonyl group include 1-tert-butoxy-2-tert-butoxycarbonyl-1,2-dihydroisoquinoline, di-tert-butyldicarbonate, 1-tert-butoxycarbonyl-1,2,4-triazole, N-(tert-butoxycarbonyloxy)phthalimide, N-tert-butoxycarbonylimidazole, and tert-butyl phenyl carbonate.

The compound represented by Formula (M1) in which R¹ is a tert-butoxycarbonyl group can be synthesized by reacting 6-bromo-7-tert-butoxycarbonyloxy-4-hydroxymethylcoumarin with an aminosilane compound.

When the compound represented by Formula (M1) is a compound in which R¹ is an ester-based protecting group, first, 6-bromo-4-hydroxymethyl-7-hydroxycoumarin is reacted with a compound containing an ester-based protecting group precursor to synthesize an intermediate.

Examples of compounds containing an ester-based protecting group include acetyl chloride, acetic anhydride, pivaloyl chloride, pivalic anhydride, benzoyl chloride, and benzoic anhydride.

The compound represented by Formula (M1) in which R¹ is an ester-based protecting group can be synthesized by reacting the obtained intermediate with an aminosilane compound.

In one aspect of the present invention, the photosensitive surface treating agent contains the compound represented by Formula (M1).

In one aspect of the present invention, the photosensitive surface treating agent may contain a solvent. By dissolving it in a general organic solvent such as an alcohol-based solvent, an ester-based solvent, a hydrocarbon aromatic solvent, an amine-based solvent, a ketone-based solvent, a glycol ether-based solvent, or an ether-based solvent as a solvent, it can be used as a suitable surface treating agent.

Examples of alcohol-based solvents include isopropyl alcohol (IPA) and n-butyl alcohol (n-butanol).

Examples of ester-based solvents include ethyl acetate (EAC), butyl acetate (NBAC), n-propyl acetate (NPAC), and 3-methoxy-3-methylbutyl acetate.

Examples of hydrocarbon aromatic solvents include toluene, xylene, benzene, ethylbenzene, and trimethylbenzene.

Examples of amine-based solvents include N-methyl-2-pyrrolidone (NMP), dimethylformamide (DMF), and N,N-dimethylacetamide (DMAC).

Examples of ketone-based solvents include methyl ethyl ketone (MEK), methyl isobutyl ketone (MIBK), diisobutyl ketone (DIBK), methyl isopropyl ketone (MIPK), cyclohexanone, cyclopentanone (CPN), cycloheptanone, and acetone.

Examples of glycol ether-based solvents include methyl cellosolve, butyl cellosolve, ethylene glycol mono t-butyl ether (ETB), propylene glycol monomethyl ether (PGME), pro-ether-based solvent pyrene glycol monomethyl ether acetate (PGMEA), and 3-methoxy-3-methyl-1-butanol (MMB).

Examples of other solvents include halogen-based solvents containing chlorine or fluorine, such as chloroform, chlorobenzene, and fluoroalkyl ether. One of these compounds may be used alone or one or more thereof may be used in combination.

The organic solvent can be appropriately selected depending on conditions such as pollution, solubility, volatility, attack on a substrate or a base, a film formation device and a film formation method.

In order to increase the reactivity between a base coating agent and a photosensitive surface treating agent, or between molecules within a photosensitive surface treating agent, the contained solvent is preferably an alcohol-based, ether-based, or hydrocarbon-based solvent, particularly a hydrocarbon-based solvent, and among these, toluene is preferable.

In order to further increase the reactivity, any acidic or basic compound may be incorporated during film formation. It can be appropriately selected depending on film formation conditions, and acidic compounds such as hydrochloric acid, acetic acid, and nitric acid are particularly preferable, and among these, acetic acid is preferable because it allows film formation while maintaining Boc.

### <Pattern Forming Method>

A pattern forming method of the present embodiment includes a step of applying the photosensitive surface treating agent of the present embodiment onto a substrate to form a resin film, a step of deprotecting the resin film to form a photosensitive resin film, a step of emitting predetermined pattern light to the photosensitive resin film to form an amine generation region in an exposure region, and a step of disposing an electroless plating catalyst in the amine generation region and performing electroless plating.

Hereinafter, the steps will be described with reference to the drawings.

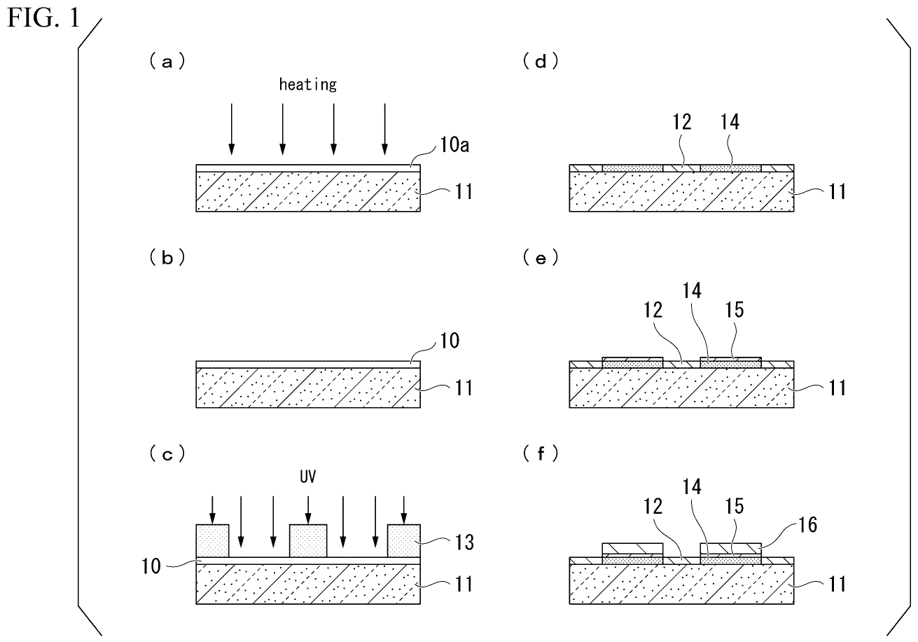

As shown in FIG. 1(a), the photosensitive surface treating agent of the present embodiment is applied onto a substrate 11 to obtain a resin film 10a.

As the coating method, coating methods such as a spin coating method, a dip coating method, a die coating method, a spray coating method, a roll coating method, a microgravure method, a lip coating method, an inkjet method, applicator coating, and brush coating can be used. In addition, coating may be performed by a printing method such as flexographic printing or screen printing.

Here, in this step, as shown in FIG. 1(a), for example, a treatment of drying the solvent by heat or decompression may also be added.

The resin film is subjected to a deprotection treatment, and a photosensitive resin layer 10 is formed. The deprotection treatment is specifically a hydrolysis treatment under acidic conditions using hydrochloric acid, sulfuric acid, hydrofluoric acid, hexafluoride antimonite or trifluoroacetic acid. The deprotection treatment may be performed in a liquid phase, or in a solid phase in contact with a gel or film. The gel or film may be in the form of a sheet or roll.

Thereby, as shown in FIG. 1(b), a photosensitive surface treating agent layer 10 is formed on the substrate 11.

The deprotection treatment may be performed immediately after the formation of the resin film, and deprotection may be performed immediately before exposure in order to increase the storage stability of the resin film.

Next, as shown in FIG. 1(c), a photomask 13 having an exposure region with a predetermined pattern is prepared. The exposure method is not limited to the method using a photomask, and methods such as projection exposure using an optical system such as a lens and a mirror, and maskless exposure using a spatial light modulation element and a laser beam can be used. Here, the photomask 13 may be provided to come into contact with the photosensitive surface treating agent layer 10 or may be provided to not come into contact therewith.

During exposure, the surface of the photosensitive resin layer may be exposed while immersed in any liquid or may be exposed after immersion. The type of the liquid is not particularly limited, and water, an alcohol-based solvent or a ketone-based solvent can be selected. One of these compounds may be used alone or one or more thereof may be used in combination.

In order to increase the acid dissociation constant (Ka), a basic compound may be added to prepare any basic solution. Regarding the type of the basic compound, any can be selected from among alkali metal carbonates such as sodium bicarbonate and potassium carbonate, alkali metal hydrides such as sodium hydride and sodium tetraborohydride, alkali metal hydroxides such as cesium hydroxide, lithium hydroxide, sodium hydroxide, and potassium hydroxide, quaternary ammonium salts such as tetramethylammonium hydroxide (TMAH), tetraethylammonium hydroxide (TEAH), tetrapropylammonium hydroxide (TPAH), and tetrabutylammonium hydroxide (TBAH), metal alkoxides such as sodium methoxide and potassium t-butoxide, metal amides such as lithium diisopropylamide (LDA) and potassium hexamethyldisilazide (KHMDS), metal alkyls such as alkyl lithium and alkyl aluminum, nitrogen-containing aliphatic compounds such as pyridinetetraethylamine, DBU, DBN, and imidazole, and nitrogen-containing heterocyclic compounds. One of these compounds may be used alone or one or more thereof may be used in combination.

The liquid is preferably a liquid composition that does not cause peeling, decomposition or dissolution of a substrate, a base, or a photosensitive surface treating agent layer, has favorable removability by washing and allows a higher pKa to be obtained, and among these, a liquid in which quaternary ammonium is added to water or an alcohol-based solvent is preferable. A tetrabutylammonium hydroxide (TBAH) aqueous solution is particularly preferable.

The purpose of increasing the pKa is to activate the hydroxy group contained in hydroxycoumarin, increase the molar absorption coefficient, and improve the photoreaction rate. When appropriate basic conditions are set, it is possible to improve the photoreactivity without damaging the photosensitive surface treating agent layer.

Then, as shown in FIG. 1(c), UV light is emitted to the photosensitive surface treating agent layer 10 through the photomask 13. Thereby, in the exposure region of the photomask 13, the photosensitive surface treating agent layer 10 is exposed.

As a result, as shown in FIG. 1(d), an amine-generated portion 14 is formed in an exposed part, and an amine-ungenerated portion 12 is formed in an unexposed part.

Examples of UV light include an i-line with a wavelength of 365 nm. In addition, the exposure amount and exposure time need not be sufficient for the deprotection to completely progress, and it is sufficient if some amines are generated.

Next, as shown in FIG. 1(e), an electroless plating catalyst is applied to the surface to form a catalyst layer 15. The electroless plating catalyst is a catalyst that reduces metal ions contained in a plating solution for electroless plating, and examples thereof include silver and palladium.

An amino group is exposed on the surface of the amine-generated portion 14. The amino group can capture and reduce the above electroless plating catalyst. Therefore, the electroless plating catalyst is captured only on the amine-generated portion 14, and the catalyst layer 15 is formed. In addition, the electroless plating catalyst that can support an amino group can be used.

As shown in FIG. 1(f), an electroless plating treatment is performed to form a plating layer 16. Here, the plating layer 16 may be made of a material such as nickel-phosphorus (NiP) or copper (Cu).

In this step, the substrate 11 is immersed in an electroless plating bath to reduce metal ions on the surface of the catalyst and deposit the plating layer 16. In this case, since the catalyst layer 15 that supports a sufficient amount of a catalyst is formed on the surface of the amine-generated portion 14, the plating layer 16 can be selectively deposited only on the amine-generated portion 14.

By the above step, it is possible to form a wiring pattern on a predetermined substrate using the photosensitive surface treating agent of the present embodiment.

### Method of Producing Transistor

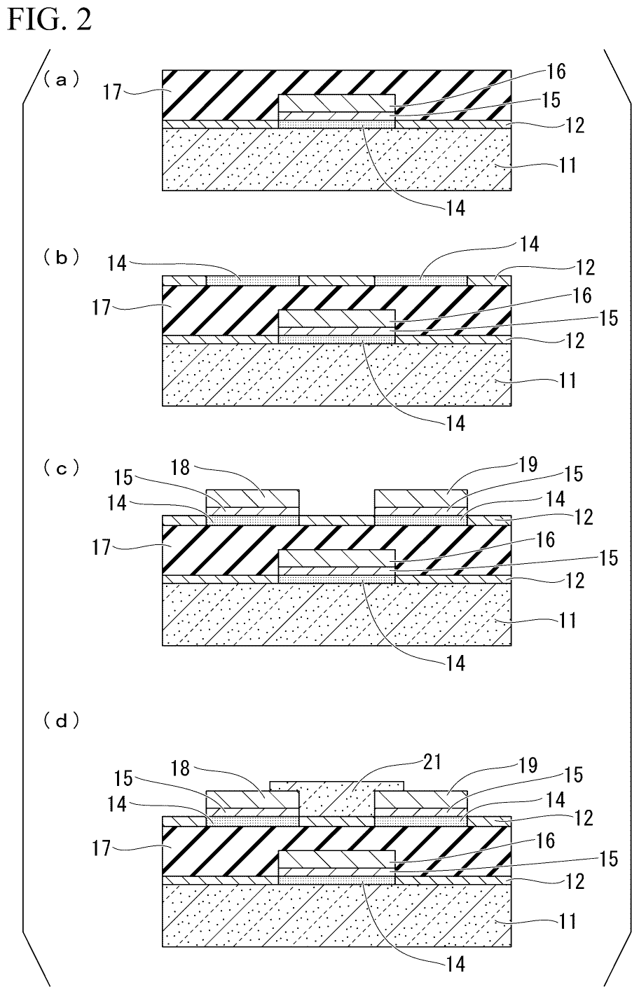

In addition, a method of producing a transistor in which the plating layer 16 obtained by the above <Pattern forming method> is used as a gate electrode will be described with reference to FIG. 2.

As shown in FIG. 2(a), an insulator layer 17 is formed by a known method to cover the plating layer 16 with an electroless plating pattern formed by the above pattern forming method and the amine-ungenerated portion 12. The insulator layer 17 may be formed by using, for example, a coating solution in which one or more resins of a UV-curable acrylic resin, an epoxy resin, an ene-thiol resin, a silicone resin and the like are dissolved in an organic solvent and applying the coating solution. When ultraviolet rays are emitted to a coating film through a mask having an opening corresponding to the region in which the insulator layer 17 is to be formed, the insulator layer 17 can be formed into a desired pattern. Here, before the insulator layer 17 is formed, the amine-ungenerated portion 12 may be removed as necessary.

As shown in FIG. 2(b), in the same manner as in the above electroless plating pattern forming method, the photosensitive surface treating agent layer 10 is formed on the insulator layer 17, and the amine-generated portion 14 is formed in a portion in which a source electrode and a drain electrode are formed.

As shown in FIG. 2(c), in the same manner as in the above pattern forming method, the electroless plating catalyst is supported on the amine-generated portion 14, the catalyst layer 15 is formed, and electroless plating is then performed to form a plating layer 18 (source electrode) and a plating layer 19 (drain electrode). Here, the plating layers 18 and 19 may be made of a material such as nickel-phosphorus (NiP) or copper (Cu), but may be made of a material different from that of the plating layer 16 (gate electrode), and a different metal such as gold (Au) may be deposited on the surface of nickel-phosphorus (NiP) or copper (Cu), for example, by performing electroless gold plating.

As shown in FIG. 2(d), a semiconductor layer 21 is formed between the plating layer 18 (source electrode) and the plating layer 19 (drain electrode).

For example, the semiconductor layer 21 may be formed by preparing a solution obtained by dissolving an organic semiconductor material soluble in an organic solvent such as TIPS pentacene (6,13-Bis(triisopropylsilylethynyl)pentacene) in the organic solvent, applying the solution between the plating layer 18 (source electrode) and the plating layer 19 (drain electrode) and performing drying.

In addition, the semiconductor layer 21 may be formed by adding one or more types of insulating polymers such as polystyrene (PS) or polymethyl methacrylate (PMMA) to the solution, applying a solution containing the insulating polymers and performing drying.

When the semiconductor layer 21 is formed in this manner, the insulating polymer is concentrated and formed below the semiconductor layer 21 (the side of the insulator layer 17). When there is a polar group such as an amino group at the interface between the organic semiconductor and the insulator layer, transistor properties tend to deteriorate, but when the organic semiconductor is provided via the above insulating polymer, it is possible to prevent transistor properties from deteriorating. As described above, it is possible to produce a transistor.

According to the above method, there is no need to provide a separate chemical resist or the like in the UV exposure step, and the step can be simplified using only a photomask. Therefore, it is needless to say that there is no need for a step of removing the resist layer. In addition, due to the catalyst reduction ability of the amino group, it is possible to omit a catalyst activation treatment step that is generally required, and high-definition patterning can be performed while achieving significant cost reduction and time saving. In addition, since the dip coating method can be used, it can also be used in the roll-to-roll step with significantly favorable compatibility.

In addition, the resin film protected with Boc is extremely stable against light, and there is no need to store it in a light-shielded place or operate it in a yellow room during a film formation operation from the state of the surface treating agent, or even in the resin film after film formation, and thus significant improvement in workability and improvement in storage stability are achieved compared to handling of general photosensitive materials. Since the photosensitivity is obtained after the deprotection treatment for expression, it is possible to significantly reduce the number of steps that require light control and it is possible to reduce the burden on operators.

Here, the structure of the transistor is not particularly limited, and can be appropriately selected depending on the purpose. For example, a top-contact/bottom-gate type transistor, a top-contact/top-gate type transistor, and a bottom-contact/top-gate type transistor may be produced in the same manner.

### Laminate

The present embodiment is a laminate containing the photosensitive surface treating agent of the present embodiment.

The laminate of the present embodiment is a laminate in which a substrate and a metal pattern are laminated, and contains a photosensitive surface treating agent in an unexposed part in which no pattern is formed.

### Transistor

The present embodiment is a transistor containing the photosensitive surface treating agent of the present embodiment.

The laminate of the present embodiment is a transistor having a laminate in which a substrate and a metal pattern are laminated, and contains a photosensitive surface treating agent in an unexposed part in which no pattern is formed.

### EXAMPLES

The present invention will be described below in more detail with reference to examples, but the present invention is not limited to the following examples.

### Example 1

A compound represented by (M1)-11 was obtained by the following synthesis scheme.

First, by the following reaction, 6-bromo-4-chloromethyl-7-hydroxycoumarin was synthesized.

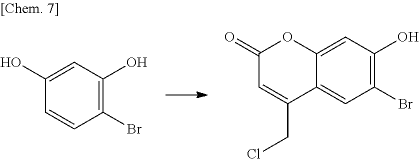 [SMILES: Oc1ccc(Br)c(O)c1 ; O=c1cc(CCl)c2cc(Br)c(O)cc2o1]

20.0 g of 4-bromoresorcinol (106 mmol, 1.0 eq) was put into a 1 L eggplant flask and dissolved in 160 mL of methanesulfonic acid (MsOH), 26.1 g of ethyl 4-chloroacetoacetate (159 mmol, 1.5 eq) was added, and the mixture was stirred at room temperature for 2 hours. The reaction solution was placed in an ice bath, 480 mL of cold water (three times the amount of MsOH) was added, and the mixture was stirred at 0° C. for 1 hour. The mixture was filtered through a membrane filter, washed with H₂O, and vacuum-dried (in a water bath at 60° C.) to obtain 29.5 g (102 mmol, 96%) of a desired light brown powder product.

¹H NMR (CD₃OD, 400 MHz): δ=4.82 (2H, d, J=0.8 Hz), 6.42 (1H, t, J=0.8 Hz), 6.85 (1H, s), 7.95 (1H, s)

Next, by the following reaction, 6-bromo-4-hydroxymethyl-7-hydroxycoumarin was synthesized.

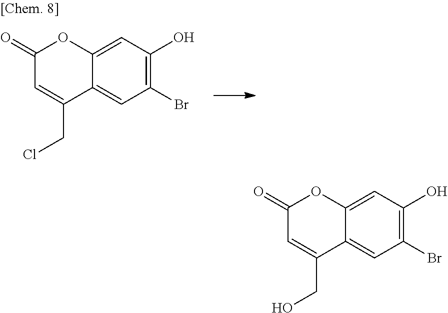 [SMILES: O=c1cc(CCl)c2cc(Br)c(O)cc2o1 ; O=c1cc(CO)c2cc(Br)c(O)cc2o1]

26.0 g of 6-bromo-4-chloromethyl-7-hydroxycoumarin (89.8 mmol, 1.0 eq), 130 mL of dimethylformamide (DMF), and 130 mL of 1 N HCl were put into a 1 L eggplant flask, and the mixture was stirred under a nitrogen atmosphere at 100° C. for 15 hours. The reaction solution was placed in an ice bath, 390 mL of cold water was added, and the mixture was stirred at 0° C. for 1 hour. The mixture was filtered through a membrane filter, washed with H₂O, and vacuum-dried (in a water bath at 60° C.) to obtain 14.6 g (53.8 mmol, 60%) of a desired light brown powder product.

¹H NMR (CD₃OD, 400 MHz): δ=4.77 (2H, d, J=1.5 Hz), 6.38 (1H, t, J=1.5 Hz), 6.84 (1H, s), 7.81 (1H, s)

Next, by the following reaction,

6-bromo-7-tert-butoxycarbonyloxy-4-hydroxymethylcoumarin was synthesized.

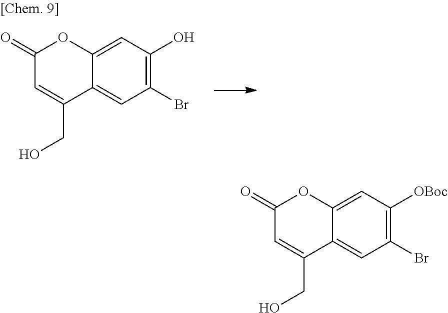

800 mg of 6-bromo-7-hydroxy-4-hydroxymethylcoumarin (2.95 mmol, 1.0 eq), 897 mg of 1-tert-butoxy-2-tert-butoxycarbonyl-1,2-dihydroisoquinoline (BBDI) (2.96 mmol, 1.0 eq), and 8 mL of anhydrous tetrahydrofuran (THF) were put into a 100 mL eggplant flask, and the mixture was stirred under a nitrogen atmosphere at room temperature for 3 hours. Extraction was performed by adding ethyl acetate (10 m×3) and 1 N HCl (10 mL), the sample was sequentially washed with a saturated NaHCO₃ aqueous solution (10 mL×1), and a saturated saline (10 mL×1), the organic layer was dried using anhydrous MgSO₄, and filtration, concentration, and vacuum-drying were performed to obtain 990 mg of a brown solid. The sample was purified (suspended in a developing solvent and charged, developing solvent chloroform: ethyl acetate=5:1 (Rf 0.29, 300 mL)) by column chromatography (silica gel 100 cc, diameter 3.0 cm, height 15 cm), concentrated, and vacuum-dried to obtain 835 mg (2.25 mmol, 76%) of a desired white solid product.

¹H NMR (CD₃OD, 400 MHz): δ=1.55 (9H, s), 4.59 (1H, br s), 4.82 (2H, d, J=1.6 Hz), 6.58 (1H, t, J=1.6 Hz), 7.37 (1H, s), 7.99 (1H, s)

Next, by the following reaction,

6-bromo-7-tert-butoxycarbonyloxycoumarin-4-ylmethyl 3-(triethoxysilyl)propylcarbamate ((M1)-11) was obtained.

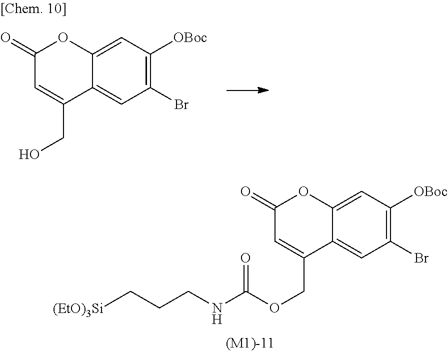

1.00 g of 6-bromo-7-tert-butoxycarbonyloxy-4-hydroxymethylcoumarin (2.69 mmol, 1.0 eq) was put into a 200 mL eggplant flask, and dissolved in 10 mL of anhydrous tetrahydrofuran (THF), 0.75 mL of triethylamine (5.41 mmol, 2.0 eq) and 670 μL of 3-(triethoxysilyl)propyl isocyanate (2.71 mmol, 1.0 eq) were added, and the mixture was stirred under a nitrogen atmosphere at 55° C. for 16 hours. The sample was concentrated using an evaporator and vacuum-dried to obtain 1.66 g of a yellow viscous material. The sample was purified (dissolved in chloroform and charged, developing solvent chloroform: ethyl acetate: tetramethoxysilane=100:5:1 (200 mL)) by column chromatography (silica gel 100 cc, diameter 3.0 cm, height 15 cm), concentrated, and vacuum-dried (in a water bath at 50° C.), then rinsed with hexane and vacuum-dried to obtain 733 mg (1.19 mmol, 44%) of a desired white powder product.

¹H NMR (CD₃OD, 400 MHz): δ=0.58-0.66 (2H, m), 1.20 (9H, t, J=7.0 Hz) 1.55 (9H, s), 1.55-1.66 (2H, m), 3.15 (2H, t, J=7.0 Hz), 3.82 (6H, q, J=7.0 Hz), 5.32 (2H, d, J=1.2 Hz), 6.48 (1H, br s), 7.38 (1H, s), 8.02 (1H, s)

### Example 2

By the following reaction, 6-bromo-7-hydroxycoumarin-4-ylmethyl 3-(triethoxysilyl)propylcarbamate (M1) was synthesized.

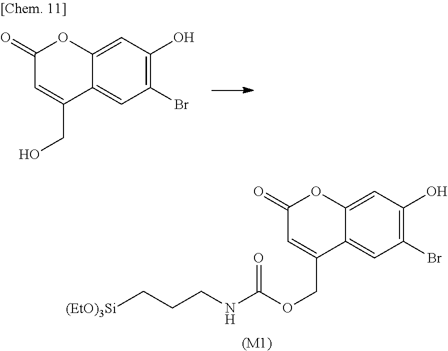

200 mg of 6-bromo-7-hydroxy-4-hydroxymethylcoumarin (0.737 mmol, 1.0 eq), 4 mL of dry THF, 2 drops (ca. 20 μL, ca. 0.05 eq) of dibutyltin dilaurate (DBTL) prepared using a pasteur, and 365 μL of 3-(triethoxysilyl)propyl isocyanate (1.48 mmol, 2.0 eq) were put into a 30 mL two-necked eggplant flask, and the mixture was stirred under a nitrogen atmosphere at 60° C. for 4 hours. The sample was concentrated using an evaporator and vacuum-dried (in a water bath at 60° C.) to obtain 560 mg of a brown viscous material. The sample was purified (dissolved in chloroform and charged, developing solvent chloroform: ethyl acetate:tetramethoxysilane=100:5:1 (120 mL)) by column chromatography (silica gel 40 cc, diameter 2.0 cm, height 15 cm), concentrated, and vacuum-dried (water bath 50° C.), then rinsed with hexane and vacuum-dried to obtain 214 mg (0.412 mmol, 56%) of a desired yellow waxy product.

Rf=0.60 (hexane:ethyl acetate=1:1)

Rf=0.25 (chloroform:ethyl acetate=20:1)

¹H NMR (CD₃OD, 400 MHz): δ=0.58-0.66 (2H, m), 1.20 (9H, t, J=7.1 Hz), 1.56-1.66 (2H, m), 3.13 (2H, t, J=7.0 Hz), 3.81 (6H, q, J=7.1 Hz), 5.27 (2H, d, J=1.2 Hz), 6.26 (1H, t, J=1.2 Hz), 6.84 (1H, s), 7.84 (1H, s)

### Evaluation

### [Plated Wiring Production 1]

A film was formed on a substrate using a surface treating agent containing a compound represented by Formula (M1)-11 to produce a plated wiring.

Toluene was added to the compound represented by Formula (M1)-11 synthesized in Example 1 to adjust the concentration to 0.1 mass %, acetic acid was additionally added in an amount such that the acetic acid concentration became 1.0 mass %, and a photosensitive surface treating agent 1 was obtained.

The photosensitive surface treating agent 1 was put into a 1.4 L glass container and heated to 60° C. using a water bath, the substrate was then immersed for 90 minutes, and the compound represented by (M1)-11 was chemically bonded onto a PET substrate having a SiO₂ film formed on its surface (VX-50TUH, commercially available from OIKE & Co., Ltd.) to form a resin film. Then, the substrate was immersed in methanol and radiated with 28 kHz ultrasonic waves for 3 minutes, physically attached compounds were removed, and a resin film having strong adhesion was obtained.

Then, the resin film was deprotected by immersing it in a mixed solution containing a 35% hydrochloric acid aqueous solution and methanol at 50:50 at room temperature for 30 minutes, and a photosensitive surface treating agent layer was obtained.

When the resin film was subjected to a deprotection treatment, as shown below, the tert-butoxycarbonyl group of the compound represented by Formula (M1)-11 was eliminated, a hydroxy group was generated, and a photosensitive resin layer was obtained.

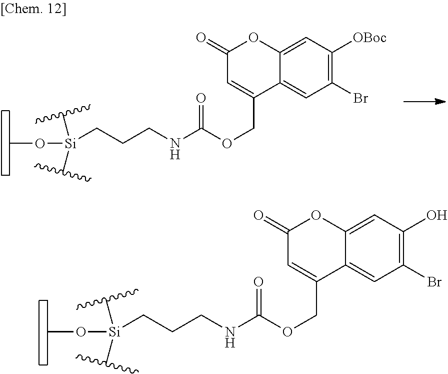

Next, the substrate in which the photosensitive surface treating agent layer was formed on the entire surface was exposed to light with a wavelength of 365 nm at 250 mJ/cm² through a photomask, the photosensitive surface treating agent layer was exposed to light, an amino group-generated portion was formed in the exposed part, and an amino group-ungenerated portion was formed in the unexposed part.

In this case, the substrate was immersed in an aqueous solution containing 0.2 mass % of tetrabutylammonium hydroxide (TBAH) and then exposed.

When the resin film was immersed, the hydroxy group of the compound represented by Formula (M1)-11 was activated by the base, the molar absorption coefficient increased, the photoreaction rate was improved, and a highly sensitive photosensitive surface treating agent layer was obtained.

Next, after washing with water, the sample was immersed in a catalyst colloidal solution for electroless plating (Melplate Activator 7331, commercially available from Meltex Inc.) at room temperature for 3 minutes, and a catalyst (Pd) was attached to the amine-generated portion. After the surface was washed with water, the sample was immersed in an electroless plating solution (Melplate NI-867, commercially available from Meltex Inc.) at 73° C. for 1 minute to deposit nickel phosphorus on the catalyst, and thereby a fine plated wiring was produced.

### [Plated Wiring Production 2]

A plated wiring was produced in the same method as in the above [Plated wiring production 1] except that the exposure amount was changed to 500 mJ/cm².

### [Plated Wiring Production 3]

A plated wiring was produced in the same method as in the above [Plated wiring production 1] except that the exposure amount was changed to 1,000 mJ/cm².

### [Plated Wiring Production 4]

A plated wiring was produced in the same method as in the above [Plated wiring production 1] except that the exposure amount was changed to 2,000 mJ/cm².

### [Plated Wiring Production 5]

A plated wiring was produced in the same method as in the above [Plated wiring production 1] except that the resin film was not deprotected, and the exposure was changed to 2,000 mJ/cm² of light with a wavelength of 365 nm while the substrate was still dry.

### [Evaluation of Plated Wiring]

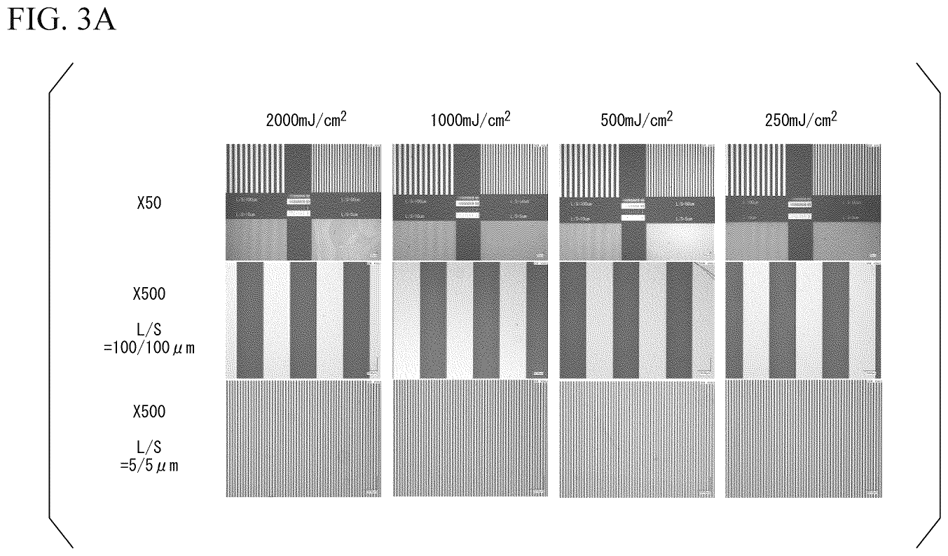

FIG. 3A and FIG. 3B show optical microscope (VHX-7000, commercially available from Keyence Corporation) images of PET substrates on which a plated wiring treatment was performed in examples.

FIG. 3A shows optical microscope images of L/S=100/100, 5/5 processed in the plated wiring productions 1 to 4 on a PET substrate.

FIG. 3B shows an optical microscope image of L/S=1/1 to 9/9 um preprocess in the plated wiring production 3 on a PET substrate.

From FIG. 3A and FIG. 3B, it was confirmed by visual inspection and using a microscope that a high-definition and favorable plated wiring could be formed.

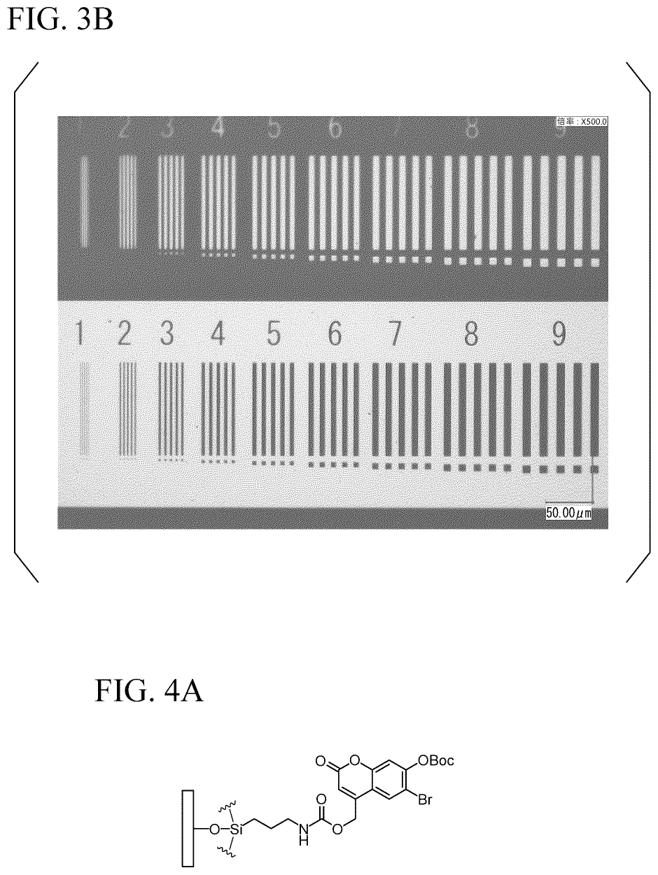

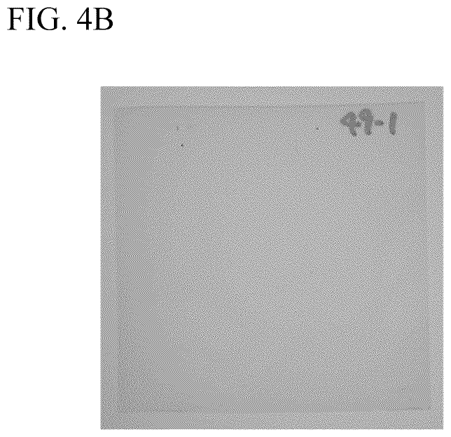

FIG. 4A and FIG. 4B show the results obtained by performing exposure and a plated wiring treatment on resin films in examples. FIG. 4A shows a molecular structure of a resin film on a PET substrate.

FIG. 4B shows an overall image of a PET substrate processed in the plated wiring production 5.

From FIG. 4A and FIG. 4B, even when light with a wavelength of 365 nm was emitted at 2,000 mJ/cm², the generation of unintended amines could be curbed without deprotection, and in the state of the resin film, amines were not unintentionally generated. That is, it was confirmed that the resin film had excellent light stability and did not require storage in a light-shielded place.

### REFERENCE SIGNS LIST

11 Substrate
10a Photosensitive surface treating agent
10 Photosensitive surface treating agent layer
13 Photomask
14 Amino group-generated portion
12 Amino group non-generated portion
15 Catalyst layer
16 Plating layer
17 Insulator layer
18 Plating layer (source electrode)
19 Plating layer (drain electrode)
21 Semiconductor layer

1. A photosensitive surface treating agent comprising a compound represented by the following Formula (M1): 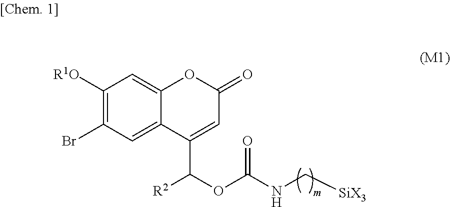
wherein in Formula (M1), R¹ is a hydrogen atom, a tert-butoxycarbonyl group or an ester-based protecting group, R² is a hydrogen atom or an alkyl group having 1 to 6 carbon atoms, m is an integer of 1 or more, and X is a halogen atom or an alkoxy group.

2. A pattern formation substrate having a surface chemically modified using the photosensitive surface treating agent according to claim 1.

3. A laminate comprising the photosensitive surface treating agent according to claim 1.

4. A transistor comprising the photosensitive surface treating agent according to claim 1.

5. A pattern forming method, comprising:
a step of applying the photosensitive surface treating agent according to claim 1 onto a substrate to form a resin film;
a step of deprotecting the resin film to form a photosensitive resin film;
a step of emitting predetermined pattern light to the photosensitive resin film; and
a step of performing electroless plating on at least a part of the region emitted with the predetermined pattern light.

6. A pattern forming method, comprising:
a step of applying the photosensitive surface treating agent according to claim 1 onto a substrate to form a resin film;
a step of deprotecting the resin film to form a photosensitive resin film;
a step of emitting predetermined pattern light to the photosensitive resin film; and
a step of disposing an electroless plating catalyst in at least a part of the region emitted with the predetermined pattern light and performing electroless plating.

7. A pattern forming method, comprising:
a step of applying the photosensitive surface treating agent according to claim 1 onto a substrate to form a resin film;
a step of deprotecting the resin film to form a photosensitive resin film;
a step of emitting predetermined pattern light to the photosensitive resin film to form an amine generation region in an exposure region; and
a step of disposing an electroless plating catalyst in the amine generation region and performing electroless plating.

8. A pattern forming method, comprising:
a step of applying the photosensitive surface treating agent according to claim 1 onto a substrate to form a resin film;
a step of deprotecting the resin film to form a photosensitive resin film;
a step of immersing the photosensitive resin film under basic solutions;
a step of emitting predetermined pattern light to the photosensitive resin film to form an amine generation region in an exposure region after the step of immersing the photosensitive resin film under the basic solutions; and
a step of disposing an electroless plating catalyst in the amine generation region and performing electroless plating.

9. A pattern forming method, comprising:
a step of applying the photosensitive surface treating agent according to claim 1 onto a substrate to form a resin film;
a step of deprotecting the resin film to form a photosensitive resin film;
a step of immersing the photosensitive resin film under basic solutions;
a step of emitting predetermined pattern light to the photosensitive resin film to form an amine generation region in an exposure region while the step of immersing the photosensitive resin film under the basic solutions; and
a step of disposing an electroless plating catalyst in the amine generation region and performing electroless plating.

10. The pattern forming method according to claim 8,
wherein the basic solutions is a tetrabutylammonium hydroxide (TBAH) aqueous solution.

11. The pattern forming method according to claim 9,
wherein the basic solutions is a tetrabutylammonium hydroxide (TBAH) aqueous solution.

12. A method of producing a transistor, comprising
a step of forming at least one of a source electrode, a drain electrode, and a gate electrode by the pattern forming method according to claim 5.

13. A method of producing a transistor, comprising
a step of forming at least one of a source electrode, a drain electrode, and a gate electrode by the pattern forming method according to claim 6.

14. A transistor comprising a compound represented by the following Formula (M1): 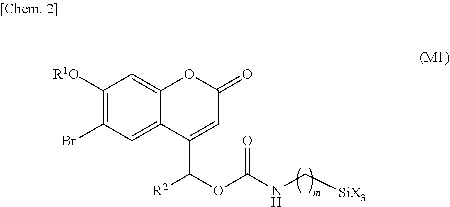
wherein in Formula (M1), R¹ is a hydrogen atom, a tert-butoxycarbonyl group or an ester-based protecting group, R² is a hydrogen atom or an alkyl group having 1 to 6 carbon atoms, m is an integer of 1 or more, and X is a halogen atom or an alkoxy group.

15. The transistor according to claim 14,
wherein the compound has a portion in which at least some nitrobenzyl groups are eliminated and amino groups are generated.
